(19) United States
(12) Patent Application Publication
(10) Pub. No.: US 2025/0087411 A1
(43) Pub. Date: Mar. 13, 2025

(54) INSULATING DEVICE AND METHOD FOR MANUFACTURING INSULATING DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Kazuyuki ITO, Fujisawa (JP); Satoshi AKUTSU, Yokohama (JP); Masahiro NARASAKI, Yokohama (JP); Takuo KIKUCHI, Kamakura (JP); Nobuaki MAKINO, Fujisawa (JP); Tatsuya OHGURO, Yokohama (JP); Yoshihiko FUJI, Nakatsu (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 18/604,349

(22) Filed: Mar. 13, 2024

(30) Foreign Application Priority Data
Sep. 13, 2023 (JP) 2023-148771

(51) Int. Cl. H01F 27/32; C23C 16/30; C23C 16/40; C23C 16/56; H01F 41/12

(52) U.S. Cl. CPC H01F 27/323; C23C 16/308; C23C 16/401; C23C 16/56; H01F 41/122

(57) ABSTRACT

An insulating device includes an insulating part, and first and second coils. The insulating part includes first to third insulating layers. The first insulating layer includes a first central insulating region and a first outer perimeter insulating region. The second insulating layer includes a second central insulating region and a second outer perimeter insulating region. The third insulating layer includes a third central insulating region and a third outer perimeter insulating region. The third central insulating region includes a first center portion including silicon oxide. The third outer perimeter insulating region includes first and second outer perimeter portions. The first outer perimeter portion includes silicon oxide. The second outer perimeter portion includes silicon oxynitride. A thickness of the first center portion is greater than that of the first outer perimeter portion. A thickness of the second outer perimeter portion is greater than that of the first outer perimeter portion.

### CROSS-REFERENCE TO RELATED APPLICATIONS

This application is based upon and claims the benefit of priority from Japanese Patent Application No. 2023-148771, filed on Sep. 13, 2023; the entire contents of which are incorporated herein by reference.

### FIELD

Embodiments described herein relate generally to an insulating device and a method for manufacturing an insulating device.

### BACKGROUND

An insulating device transmits a signal by utilizing the change of a magnetic field or electric field in a state in which the current is blocked. It is desirable to both improve insulation life and suppress warp of such an insulating device.

### BRIEF DESCRIPTION OF THE DRAWINGS

FIG. 1 is a plan view illustrating an insulating device according to a first embodiment;

FIG. 2 is a cross-sectional view illustrating the insulating device according to the first embodiment;

FIG. 3 is a cross-sectional view illustrating an insulating device according to a second embodiment;

FIG. 4 is a cross-sectional view illustrating an insulating device according to a third embodiment;

FIGS. 5A to 5D are cross-sectional views illustrating a method for manufacturing the insulating device according to the first embodiment;

FIGS. 6A to 6D are cross-sectional views illustrating a method for manufacturing the insulating device according to the first embodiment; and

FIGS. 7A to 7C are cross-sectional views illustrating a method for manufacturing the insulating device according to the first embodiment.

### DETAILED DESCRIPTION

An insulating device according to an embodiment includes an insulating part, a first coil, and a second coil. The first coil is located inside the insulating part. The second coil is located inside the insulating part. The second coil faces the first coil in the first direction. The insulating part includes a first insulating layer, a second insulating layer, and a third insulating layer. The first coil is located inside the first insulating layer. The second coil is located inside the second insulating layer. The third insulating layer is positioned between the first insulating layer and the second insulating layer in the first direction. The first insulating layer includes a first central insulating region and a first outer perimeter insulating region. The first coil is located inside the first central insulating region. The first outer perimeter insulating region surrounds the first central insulating region along a first plane perpendicular to the first direction. The second insulating layer includes a second central insulating region and a second outer perimeter insulating region. The second coil is located inside the second central insulating region. The second outer perimeter insulating region surrounds the second central insulating region along the first plane. The third insulating layer includes a third central insulating region and a third outer perimeter insulating region. The third central insulating region is positioned between the first central insulating region and the second central insulating region in the first direction. The third outer perimeter insulating region is positioned between the first outer perimeter insulating region and the second outer perimeter insulating region in the first direction. The third central insulating region includes a first center portion. The first center portion includes silicon oxide. The third outer perimeter insulating region includes a first outer perimeter portion and a second outer perimeter portion. The first outer perimeter portion includes silicon oxide. The second outer perimeter portion is positioned between the first outer perimeter portion and the second outer perimeter insulating region in the first direction. The second outer perimeter portion includes silicon oxynitride. A thickness in the first direction of the first center portion is greater than a thickness in the first direction of the first outer perimeter portion. A thickness in the first direction of the second outer perimeter portion is greater than a thickness in the first direction of the first outer perimeter portion.

A method for manufacturing an insulating device according to an embodiment includes a first process, a second process, a third process, a fourth process, a fifth process, a sixth process, a seventh process, and an eighth process. In the first process, a first silicon oxide film is formed on a first insulating layer. The first insulating layer includes a first central insulating region and a first outer perimeter insulating region. A first coil is located inside the first central insulating region. The first outer perimeter insulating region surrounds the first central insulating region. The first silicon oxide film includes a first portion and a second portion. The first portion overlaps the first central insulating region. The second portion overlaps the first outer perimeter insulating region. In the second process, a first silicon oxynitride film is formed on the first silicon oxide film. The first silicon oxynitride film includes a third portion and a fourth portion. The third portion overlaps the first portion. The fourth portion overlaps the second portion. In the third process, the first portion is exposed by removing the third portion. In the fourth process, a second silicon oxide film is formed on the first portion. In the fifth process, a second silicon oxynitride film is formed on the second silicon oxide film and the fourth portion. The second silicon oxynitride film includes a fifth portion and a sixth portion. The fifth portion overlaps the second silicon oxide film. The sixth portion overlaps the fourth portion. In the sixth process, the second silicon oxide film is exposed by removing the fifth portion. In the seventh process, a third silicon oxide film is formed on the second silicon oxide film. In the eighth process, a second insulating layer is formed on the third silicon oxide film and the sixth portion. The second insulating layer includes a second central insulating region and a second outer perimeter insulating region. The second central insulating region overlaps the third silicon oxide film. The second coil is located inside the second central insulating region. The second outer perimeter insulating region overlaps the sixth portion. The second outer perimeter insulating region surrounds the second central insulating region.

Exemplary embodiments will now be described with reference to the drawings.

The drawings are schematic or conceptual; and the relationships between the thickness and width of portions, the proportional coefficients of sizes among portions, etc., are not necessarily the same as the actual values thereof. Furthermore, the dimensions and proportional coefficients may be illustrated differently among drawings, even for identical portions.

In the specification of the application and the drawings, components similar to those described in regard to a drawing thereinabove are marked with like reference numerals; and a detailed description is omitted as appropriate.

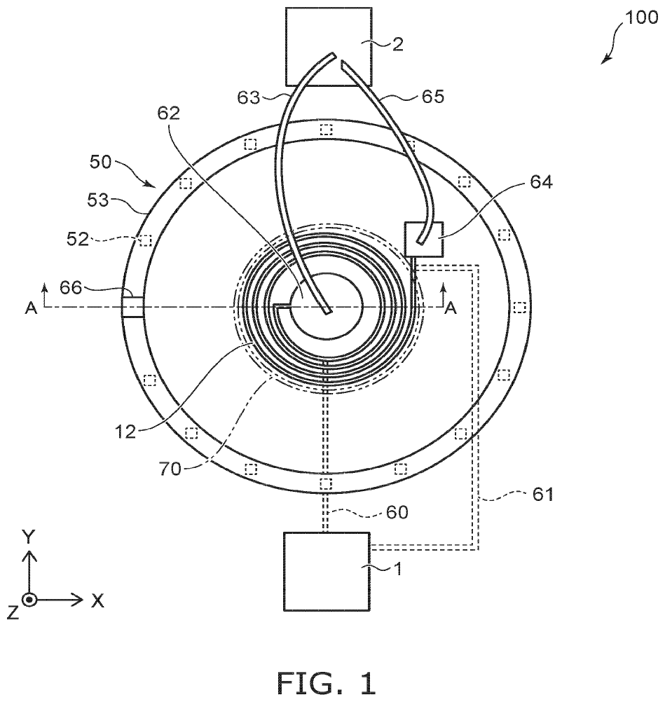

FIG. 1 is a plan view illustrating an insulating device according to a first embodiment.

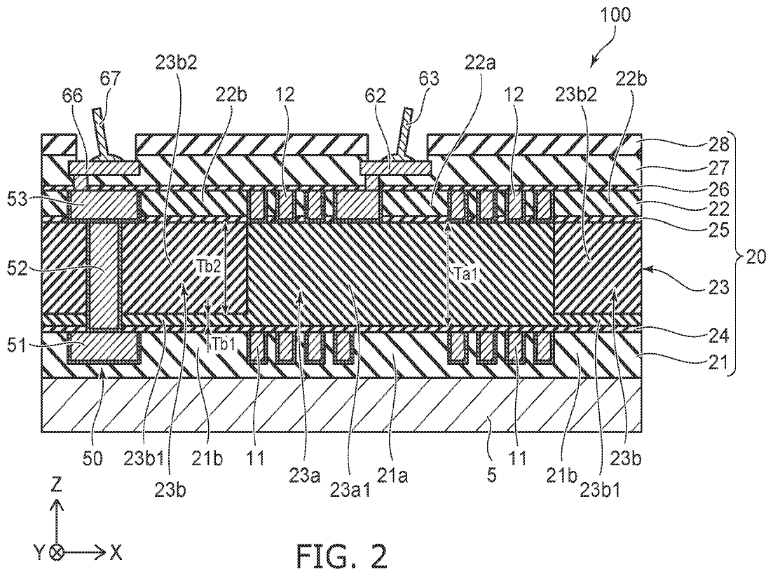

FIG. 2 is a cross-sectional view illustrating the insulating device according to the first embodiment.

FIG. 2 is a cross-sectional view along line A-A shown in FIG. 1.

The insulating device 100 according to the first embodiment is, for example, a digital isolator, a galvanic isolator, or a galvanic isolation element.

As illustrated in FIGS. 1 and 2, the insulating device 100 includes a first circuit 1, a second circuit 2, a substrate 5, a first coil 11, a second coil 12, an insulating part 20, and a conductive body 50. The insulating part 20 is located on the substrate 5. The first coil 11 and the second coil 12 are located inside the insulating part 20. The second coil 12 faces the first coil 11 in the Z-direction. The second coil 12 is located higher than the first coil 11. The conductive body 50 is located inside the insulating part 20. The conductive body 50 is located around the first coil 11 and the second coil 12.

An XYZ orthogonal coordinate system is used in the description of embodiments. The direction from the first coil 11 toward the second coil 12 is taken as a Z-direction (a first direction). Two mutually-orthogonal directions perpendicular to the Z-direction are taken as an X-direction (a second direction) and a Y-direction (a third direction). In the description, the direction from the first coil 11 toward the second coil 12 is called “up/above/higher than”, and the opposite direction is called “down/below/lower than”. These directions are based on the relative positional relationship between the first coil 11 and the second coil 12, and are independent of the direction of gravity. A first plane perpendicular to the Z-direction (the first direction) is a plane (the X-Y plane) parallel to the X-direction (the second direction) and the Y-direction (the third direction).

The insulating part 20 includes a first insulating layer 21, a second insulating layer 22, a third insulating layer 23, a fourth insulating layer 24, a fifth insulating layer 25, a sixth insulating layer 26, a seventh insulating layer 27, and an eighth insulating layer 28. In the insulating part 20, the first insulating layer 21, the fourth insulating layer 24, the third insulating layer 23, the fifth insulating layer 25, the second insulating layer 22, the sixth insulating layer 26, the seventh insulating layer 27, and the eighth insulating layer 28 are stacked in this order from below in the Z-direction. The sixth to eighth insulating layers 26 to 28 are not illustrated in FIG. 1.

As illustrated in FIG. 2, the first insulating layer 21 is located on the substrate 5. The first coil 11 is located inside the first insulating layer 21. The first coil 11 is arranged with the first insulating layer 21 in the X-direction and Y-direction. The first insulating layer 21 contacts the first coil 11. The fourth insulating layer 24 is located on the first insulating layer 21 and 35 the first coil 11. The third insulating layer 23 is located on the fourth insulating layer 24. The fourth insulating layer 24 is positioned between the first insulating layer 21 and the third insulating layer 23 and between the first coil 11 and the third insulating layer 23 in the Z-direction. The fourth insulating layer 24 contacts the first coil 11.

The fifth insulating layer 25 is located on the third insulating layer 23. The second insulating layer 22 is located on the fifth insulating layer 25. The second coil 12 is located inside the second insulating layer 22 and inside the fifth insulating layer 25. The second coil 12 is arranged with the second insulating layer 22 in the X-direction and Y-direction. The second insulating layer 22 contacts the second coil 12. The second coil 12 is arranged with the fifth insulating layer 25 in the X-direction and Y-direction. The fifth insulating layer 25 contacts the second coil 12. The fifth insulating layer 25 is positioned between the second insulating layer 22 and the third insulating layer 23 in the Z-direction. The third insulating layer 23 is positioned between the first insulating layer 21 and the second insulating layer 22 in the Z-direction. The third insulating layer 23 is positioned between the first coil 11 and the second coil 12 in the Z-direction.

The sixth insulating layer 26 is located on the second insulating layer 22. The seventh insulating layer 27 is located on the sixth insulating layer 26. The eighth insulating layer 28 is located on the seventh insulating layer 27. A pad 62 that is connected to the second coil 12 and a pad 66 that is connected to the conductive body 50 (described below) are located in the seventh and eighth insulating layers 27 and 28. The pad 62 is connected to the second circuit 2 via a wiring part 63. The pad 66 is connected with the conductive member (not illustrated) via a wiring part 67.

In the example illustrated in FIGS. 1 and 2, the first coil 11 and the second coil 12 are formed in circular spiral shapes along the first plane (the X-Y plane). The first coil 11 and the second coil 12 are not limited to circular spiral shapes and may be formed in, for example, polygonal spiral shapes. The first coil 11 and the second coil 12 face each other in the Z-direction. At least a portion of the second coil 12 is arranged with at least a portion of the first coil 11 in the Z-direction.

The conductive body 50 is located around the first coil 11 and the second coil 12 along the first plane (the X-Y plane). For example, the conductive body 50 is connected to the first coil 11. The conductive body 50 includes a first conductive part 51, a second conductive part 52, and a third conductive part 53.

The first conductive part 51 is located inside the first insulating layer 21. The first conductive part 51 is located around the first coil 11. The shape of the first conductive part 51 is, for example, circular-ring-shaped when viewed in plan. For example, the first conductive part 51 is connected to the first coil 11.

The second conductive part 52 is located on a portion of the first conductive part 51. Multiple second conductive parts 52 are arranged along the first conductive part 51. In other words, the multiple second conductive parts 52 are arranged discontinuously to be separated from each other along the circular-ring-shaped first conductive part 51. The second conductive parts 52 are located inside the fourth insulating layer 24 and the third insulating layer 23. The second conductive parts 52 extend in the Z-direction. The second conductive parts 52 have columnar shapes having the Z-direction as axes. For example, the second conductive parts 52 have quadrilateral prism shapes having the Z-direction as axes.

The third conductive part 53 is located on the multiple second conductive parts 52. The third conductive part 53 is located inside the fifth insulating layer 25 and inside the second insulating layer 22. The third conductive part 53 is located around the second coil 12. The shape of the third conductive part 53 is the same as the shape of the first conductive part 51 when viewed in plan. The third conductive part 53 is, for example, circular-ring-shaped when viewed in plan. The sixth insulating layer 26 is located on the third conductive part 53.

In the example illustrated in FIG. 1, one end of the first coil 11 (one end of the coil) is electrically connected with the first circuit 1 via a wiring part 60. The other end of the first coil 11 (the other end of the coil) is electrically connected with the first circuit 1 via a wiring part 61.

One end of the second coil 12 (one end of the coil) is electrically connected with the second circuit 2 via the pad 62 and the wiring part 63. The other end of the second coil 12 (the other end of the coil) is electrically connected with the second circuit 2 via a pad 64 and a wiring part 65. For example, the pad 62 is located on the one end of the second coil 12. The pad 64 is located on the other end of the second coil 12. The Z-direction position of the pad 62 and the Z-direction position of the pad 64 may be the same as the Z-direction position of the second coil 12. The pads 62 and 64 may be formed to have a continuous body with the second coil 12.

As illustrated in FIG. 2, the pad 66 is located on the conductive body 50. The conductive body 50 is electrically connected with a conductive member (not illustrated) via the pad 66 and the wiring part 67. For example, the conductive body 50 and the substrate 5 are connected to a reference potential. The reference potential is, for example, a ground potential. The conductive body 50 can be prevented from having a floating potential by connecting the conductive body 50 to a reference potential. As a result, leakage of the magnetic fields generated by the first and second coils 11 and 12 can be suppressed, and external magnetic fields can be prevented from reaching the first coil 11 and the second coil 12.

The first circuit 1 may be located on the substrate 5. In such a case, by locating the conductive body 50 on the first circuit 1, the first circuit 1 is shielded by the conductive body 50 from electromagnetic waves traveling toward the first circuit 1 from outside the substrate 5 and conductive body 50. As a result, the operations of the first circuit 1 can be stabilized more.

One of the first circuit 1 or the second circuit 2 is used as a transmitting circuit. The other of the first circuit 1 or the second circuit 2 is used as a receiving circuit. In the description herein, the first circuit 1 is a transmitting circuit; and the second circuit 2 is a receiving circuit.

The first circuit 1 transmits, to the first coil 11, a wave-like signal (a current) suited to transmission. When the current flows through the first coil 11, a magnetic field that passes through the interior of the spiral-shaped first coil 11 is generated. At least a portion of the first coil 11 is arranged with at least a portion of the second coil 12 in the Z-direction. A portion of the generated magnetic force lines passes through the interior of the second coil 12. An induced electromotive force is generated in the second coil 12 by the change of the magnetic field inside the second coil 12; and a current flows through the second coil 12. The second circuit 2 detects the current flowing through the second coil 12, and generates a signal corresponding to the detection result. As a result, a signal is transmitted between the first coil 11 and the second coil 12 in a state in which the current is blocked (insulated).

Examples of the materials of the components of the insulating device 100 will now be described.

The first coil 11, the second coil 12, and the conductive body 50 include, for example, metals. The first coil 11, the second coil 12, and the conductive body 50 include, for example, at least one metal selected from the group consisting of copper and aluminum. It is favorable for the electrical resistances of the first and second coils 11 and 12 to be low to suppress heat generation when the first coil 11 and the second coil 12 transmit the signal. It is favorable for the first and second coils 11 and 12 to include copper. By the first coil 11 and the second coil 12 including copper, the electrical resistance can be reduced.

The first insulating layer 21, the second insulating layer 22, the third insulating layer 23, and the seventh insulating layer 27 include silicon and oxygen. The first insulating layer 21, the second insulating layer 22, the third insulating layer 23, and the seventh insulating layer 27 include, for example, silicon oxide. The first insulating layer 21, the second insulating layer 22, the third insulating layer 23, and the seventh insulating layer 27 may further include nitrogen.

The eighth insulating layer 28 includes an insulating resin such as polyimide, polyamide, etc. The fourth insulating layer 24 and the sixth insulating layer 26 include silicon and nitrogen. The fourth insulating layer 24 and the sixth insulating layer 26 include, for example, silicon nitride. The substrate 5 includes silicon and an impurity. The impurity includes at least one selected from the group consisting of boron, phosphorus, arsenic, and antimony.

The fifth insulating layer 25 includes at least one selected from the group consisting of a first material including silicon and nitrogen, a second material including aluminum and oxygen, a third material including tantalum and oxygen, a fourth material including hafnium and oxygen, a fifth material including zirconium and oxygen, a sixth material including strontium, titanium, and oxygen, a seventh material including bismuth, iron, and oxygen, and an eighth material including barium, titanium, and oxygen. The fifth insulating layer 25 includes, for example, silicon nitride. The relative dielectric constant of the fifth insulating layer 25 is, for example, greater than the relative dielectric constant of the third insulating layer 23. The relative dielectric constant of the fifth insulating layer 25 is, for example, greater than the relative dielectric constant of the second insulating layer 22.

The first insulating layer 21, the second insulating layer 22, and the third insulating layer 23 will now be described in more detail.

As illustrated in FIG. 2, the first insulating layer 21 includes a first central insulating region 21a and a first outer perimeter insulating region 21b. The first central insulating region 21a is positioned at the center of the first insulating layer 21 when viewed in plan. The first central insulating region 21a includes, for example, the center of the first insulating layer 21 when viewed in plan. The first outer perimeter insulating region 21b is positioned outward of the first central insulating region 21a when viewed in plan. The first outer perimeter insulating region 21b surrounds the first central insulating region 21a along the first plane (the X-Y plane). That is, the first outer perimeter insulating region 21b is located at the periphery of the first central insulating region 21a when viewed in plan. The first coil 11 is located inside the first central insulating region 21a.

As illustrated in FIG. 2, the second insulating layer 22 includes a second central insulating region 22a and a second outer perimeter insulating region 22b. The second central insulating region 22a is positioned at the center of the second insulating layer 22 when viewed in plan. The second central insulating region 22a includes, for example, the center of the second insulating layer 22 when viewed in plan. The second outer perimeter insulating region 22b is positioned outward of the second central insulating region 22a when viewed in plan. The second outer perimeter insulating region 22b surrounds the second central insulating region 22a along the first plane (the X-Y plane). That is, the second outer perimeter insulating region 22b is located at the periphery of the second central insulating region 22a when viewed in plan. The second coil 12 is located inside the second central insulating region 22a.

As illustrated in FIG. 2, the third insulating layer 23 includes a third central insulating region 23a and a third outer perimeter insulating region 23b. The third central insulating region 23a is positioned at the center of the third insulating layer 23 when viewed in plan. The third central insulating region 23a includes, for example, the center of the third insulating layer 23 when viewed in plan. The third outer perimeter insulating region 23b is positioned outward of the third central insulating region 23a when viewed in plan. The third outer perimeter insulating region 23b surrounds the third central insulating region 23a along the first plane (the X-Y plane). That is, the third outer perimeter insulating region 23b is located at the periphery of the third central insulating region 23a when viewed in plan. The third central insulating region 23a is positioned between the first central insulating region 21a and the second central insulating region 22a in the Z-direction. The third outer perimeter insulating region 23b is positioned between the first outer perimeter insulating region 21b and the second outer perimeter insulating region 22b in the Z-direction.

The third central insulating region 23a includes a first center portion 23a1. In the insulating device 100, the third central insulating region 23a is made of the first center portion 23a1. In the insulating device 100, the third central insulating region 23a does not include another portion (a second center portion 23a2 described below) positioned between the first center portion 23a1 and the second outer perimeter insulating region 22b in the Z-direction. The first center portion 23a1 includes silicon oxide. For example, the first center portion 23a1 is made of silicon oxide. The first center portion 23a1 is, for example, a multilayer film that includes silicon oxide.

The third outer perimeter insulating region 23b includes a first outer perimeter portion 23b1 and a second outer perimeter portion 23b2. The second outer perimeter portion 23b2 is positioned between the first outer perimeter portion 23b1 and the second outer perimeter insulating region 22b in the Z-direction. The first outer perimeter portion 23b1 is positioned between the second outer perimeter portion 23b2 and the first outer perimeter insulating region 21b in the Z-direction. The first outer perimeter portion 23b1 includes silicon oxide. For example, the first outer perimeter portion 23b1 is made of silicon oxide. The second outer perimeter portion 23b2 includes silicon oxynitride. For example, the second outer perimeter portion 23b2 is made of silicon oxynitride. The second outer perimeter portion 23b2 is, for example, a multilayer film that includes silicon oxynitride. The second outer perimeter portion 23b2 may include, for example, carbon at a concentration of about the concentration of an impurity. The first center portion 23a1 is arranged with the first outer perimeter portion 23b1 in the X-direction and Y-direction. The first center portion 23a1 is arranged with the second outer perimeter portion 23b2 in the X-direction and Y-direction.

A thickness Ta1 in the Z-direction of the first center portion 23a1 is greater than a thickness Tb1 in the Z-direction of the first outer perimeter portion 23b1. A thickness Tb2 in the Z-direction of the second outer perimeter portion 23b2 is greater than the thickness Tb1. The thickness Ta1 is, for example, greater than the thickness Tb2. The thickness Ta1 is, for example, about 10 μm. The thickness Tb1 is, for example, not less than 50 nm. The thickness Tb2 is, for example, about 10 μm.

In the insulating device 100 as described above, the third central insulating region 23a does not include another portion (the second center portion 23a2 described below) positioned between the first center portion 23a1 and the second outer perimeter insulating region 22b in the Z-direction. That is, in the insulating device 100, the third central insulating region 23a includes only the first center portion 23a1 including silicon oxide, and does not include a portion including silicon oxynitride. In other words, the upper end of the first center portion 23a1 is arranged with the upper end of the second outer perimeter portion 23b2 in the X-direction and Y-direction. The lower end of the first center portion 23a1 is arranged with the lower end of the first outer perimeter portion 23b1 in the X-direction and Y-direction. The thickness Ta1 is, for example, equal to the total of the thicknesses Tb1 and Tb2.

Effects of the insulating device 100 will now be described.

In a conventional insulating device, an inter-layer insulating film having a two-layer structure is formed between electrodes above and below, in which the two-layer structure includes a silicon oxide layer, and a silicon oxynitride layer located on the silicon oxide layer. For example, in such an insulating device, it may be considered to improve the insulation life by increasing the silicon oxide ratio. For a low electric field (e.g., about 1 MV/cm), the insulation life of silicon oxide is greater than the insulation life of silicon oxynitride. Therefore, the insulation life is easily improved by increasing the silicon oxide ratio. When, however, the silicon oxide layer is made thicker to increase the silicon oxide ratio, warp of the insulating device easily increases due to the stress generated when forming the inter-layer insulating film. That is, in a conventional insulating device, it is difficult to both improve the insulation life and suppress the warp.

In the insulating device 100, the third central insulating region 23a that is positioned between the first coil 11 and the second coil 12 includes the first center portion 23a1 including silicon oxide. Also, the third outer perimeter insulating region 23b that is not positioned between the first coil 11 and the second coil 12 includes the first outer perimeter portion 23b1 including silicon oxide and the second outer perimeter portion 23b2 including silicon oxynitride. The thickness Ta1 of the first center portion 23a1 is greater than the thickness Tb1 of the first outer perimeter portion 23b1; and the thickness Tb2 of the second outer perimeter portion 23b2 is greater than the thickness Tb1 of the first outer perimeter portion 23b1. As a result, the insulation life can be improved by increasing the ratio of silicon oxide, which has a greater insulation life than silicon oxynitride, at the portion positioned between the first coil 11 and the second coil 12; and the warp can be suppressed by increasing the ratio of silicon oxynitride, which has less stress than silicon oxide, at portions not positioned between the first coil 11 and the second coil 12. Accordingly, both the improvement of the insulation life and the suppression of the warp can be realized, and the reliability can be increased.

In the insulating device 100, the thickness Ta1 of the first center portion 23a1 is greater than the thickness Tb2 of the second outer perimeter portion 23b2. As a result, both the improvement of the insulation life and the suppression of the warp can be realized with better balance.

In the insulating device 100, the thickness Ta1 of the first center portion 23a1 is equal to the total of the thickness Tb1 of the first outer perimeter portion 23b1 and the thickness Tb2 of the second outer perimeter portion 23b2. That is, in the insulating device 100, the third central insulating region 23a includes only the first center portion 23a1 including silicon oxide, and does not include a portion including silicon oxynitride. As a result, both the improvement of the insulation life and the suppression of the warp can be realized with better balance.

In the insulating device 100, the first center portion 23a1 is a multilayer film including silicon oxide. The second outer perimeter portion 23b2 is a multilayer film including silicon oxynitride. As a result, stress when forming the first center portion 23a1 or the second outer perimeter portion 23b2 can be suppressed. Accordingly, the warp can be further suppressed.

### Second Embodiment

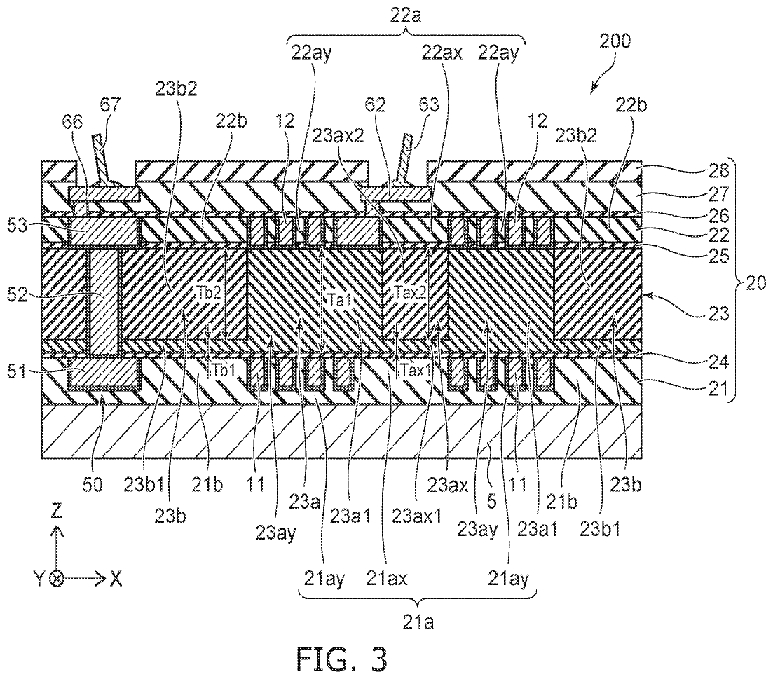

FIG. 3 is a cross-sectional view illustrating an insulating device according to a second embodiment.

FIG. 3 is a cross-sectional view at the same position as FIG. 2.

As illustrated in FIG. 3, the structure of the third insulating layer 23 of the insulating device 200 according to the second embodiment is different from that of the insulating device 100. Otherwise, the insulating device 200 is the same as the insulating device 100.

In the insulating device 200, the first central insulating region 21a of the first insulating layer 21 includes a first center portion 21ax and a first middle portion 21ay. The first center portion 21ax is positioned at the center of the first central insulating region 21a when viewed in plan. The first center portion 21ax includes, for example, the center of the first central insulating region 21a when viewed in plan. The first middle portion 21ay is positioned outward of the first center portion 21ax when viewed in plan. The first middle portion 21ay surrounds the first center portion 21ax along the first plane (the X-Y plane). That is, the first middle portion 21ay is located at the periphery of the first center portion 21ax when viewed in plan. The first middle portion 21ay is positioned between the first center portion 21ax and the first outer perimeter insulating region 21b in the X-direction and Y-direction. The first coil 11 is located inside the first middle portion 21ay. The first center portion 21ax is positioned at the center of the spiral-shaped first coil 11.

In the insulating device 200, the second central insulating region 22a of the second insulating layer 22 includes a second center portion 22ax and a second middle portion 22ay. The second center portion 22ax is positioned at the center of the second central insulating region 22a when viewed in plan. The second center portion 22ax includes, for example, the center of the second central insulating region 22a when viewed in plan. The second middle portion 22ay is positioned outward of the second center portion 22ax when viewed in plan. The second middle portion 22ay surrounds the second center portion 22ax along the first plane (the X-Y plane). That is, the second middle portion 22ay is located at the periphery of the second center portion 22ax when viewed in plan. The second middle portion 22ay is positioned between the second center portion 22ax and the second outer perimeter insulating region 22b in the X-direction and Y-direction. The second coil 12 is located inside the second middle portion 22ay. The second center portion 22ax is positioned at the center of the spiral-shaped second coil 12.

In the insulating device 200, the third central insulating region 23a of the third insulating layer 23 includes a third center portion 23ax and a third middle portion 23ay. The third center portion 23ax is positioned at the center of the third central insulating region 23a when viewed in plan. The third center portion 23ax includes, for example, the center of the third central insulating region 23a when viewed in plan. The third middle portion 23ay is positioned outward of the third center portion 23ax when viewed in plan. The third middle portion 23ay surrounds the third center portion 23ax along the first plane (the X-Y plane). That is, the third middle portion 23ay is located at the periphery of the third center portion 23ax when viewed in plan. The third middle portion 23ay is positioned between the third center portion 23ax and the third outer perimeter insulating region 23b in the X-direction and Y-direction. The third center portion 23ax is positioned between the first center portion 21ax and the second center portion 22ax in the Z-direction. The third middle portion 23ay is positioned between the first middle portion 21ay and the second middle portion 22ay in the Z-direction. That is, the third middle portion 23ay overlaps the first and second coils 11 and 12 in the Z-direction. On the other hand, the third center portion 23ax does not overlap the first and second coils 11 and 12 in the Z-direction.

The third middle portion 23ay includes the first center portion 23a1. The first center portion 23a1 includes silicon oxide. For example, the first center portion 23a1 is made of silicon oxide. The first center portion 23a1 is, for example, a multilayer film including silicon oxide.

The third center portion 23ax includes a first portion 23ax1 and a second portion 23ax2. The second portion 23ax2 is positioned between the first portion 23ax1 and the second middle portion 22ay in the Z-direction. The first portion 23ax1 is positioned between the second portion 23ax2 and the first middle portion 21ay in the Z-direction. The first portion 23ax1 includes silicon oxide. For example, the first portion 23ax1 is made of silicon oxide. The second portion 23ax2 includes silicon oxynitride. For example, the second portion 23ax2 is made of silicon oxynitride. The second portion 23ax2 is, for example, a multilayer film including silicon oxynitride. The second portion 23ax2 may include, for example, carbon at a concentration of about the concentration of an impurity.

The thickness Ta1 in the Z-direction of the first center portion 23a1 (the third middle portion 23ay) is greater than the thickness Tb1 in the Z-direction of the first outer perimeter portion 23b1. The thickness Tb2 in the Z-direction of the second outer perimeter portion 23b2 is greater than the thickness Tb1. The thickness Ta1 is, for example, greater than the thickness Tb2. The thickness Ta1 in the Z-direction of the first center portion 23a1 (the third middle portion 23ay) also is greater than a thickness Tax1 in the Z-direction of the first portion 23ax1. A thickness Tax2 in the Z-direction of the second portion 23ax2 is greater than the thickness Tax1. The thickness Ta1 is, for example, greater than the thickness Tax2. The thickness Tax1 is, for example, equal to the thickness Tb1. The thickness Tax2 is, for example, equal to the thickness Tb2.

In the insulating device 200 as well, the insulation life can be improved by increasing the ratio of silicon oxide, which has a greater insulation life than silicon oxynitride, at the portion positioned between the first coil 11 and the second coil 12; and the warp can be suppressed by increasing the ratio of silicon oxynitride, which has less stress than silicon oxide, at portions not positioned between the first coil 11 and the second coil 12. Accordingly, both the improvement of the insulation life and the suppression of the warp can be realized, and the reliability can be increased.

### Third Embodiment

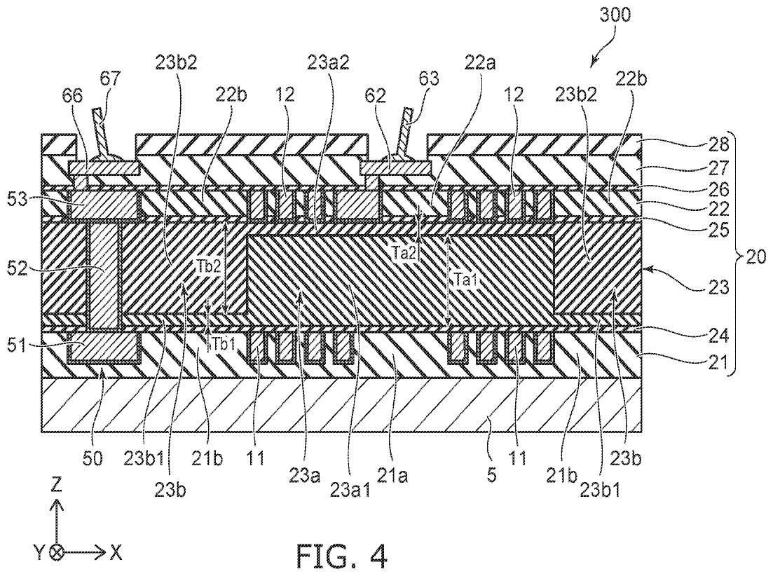

FIG. 4 is a cross-sectional view illustrating an insulating device according to a third embodiment.

FIG. 4 is a cross-sectional view at the same position as FIG. 2.

As illustrated in FIG. 4, the structure of the third insulating layer 23 of the insulating device 300 according to the third embodiment is different from that of the insulating device 100. Otherwise, the insulating device 300 is the same as the insulating device 100.

In the insulating device 300, the third central insulating region 23a of the third insulating layer 23 includes the first center portion 23a1 and the second center portion 23a2. The second center portion 23a2 is positioned between the second central insulating region 22a and the first center portion 23a1 in the Z-direction. The first center portion 23a1 is positioned between the first central insulating region 21a and the second center portion 23a2 in the Z-direction. The second center portion 23a2 is arranged with the second outer perimeter portion 23b2 in the X-direction and Y-direction. The second center portion 23a2 is not arranged with the first outer perimeter portion 23b1 in the X-direction and Y-direction. The second center portion 23a2 includes silicon oxynitride. For example, the second center portion 23a2 is made of silicon oxynitride. The second center portion 23a2 may include, for example, carbon at a concentration of about the concentration of an impurity.

The thickness Ta1 in the Z-direction of the first center portion 23a1 is greater than the thickness Tb1 in the Z-direction of the first outer perimeter portion 23b1. The thickness Tb2 in the Z-direction of the second outer perimeter portion 23b2 is greater than the thickness Tb1. The thickness Ta1 is, for example, greater than the thickness Tb2. The thickness Ta1 also is greater than a thickness Ta2 in the Z-direction of the second center portion 23a2. The thickness Tb2 is greater than the thickness Ta2.

In the insulating device 300 as well, the insulation life can be improved by increasing the ratio of silicon oxide, which has a greater insulation life than silicon oxynitride, at the portion positioned between the first coil 11 and the second coil 12; and the warp can be suppressed by increasing the ratio of silicon oxynitride, which has less stress than silicon oxide, at portions not positioned between the first coil 11 and the second coil 12. Accordingly, both the improvement of the insulation life and the suppression of the warp can be realized, and the reliability can be increased.

### Manufacturing Method

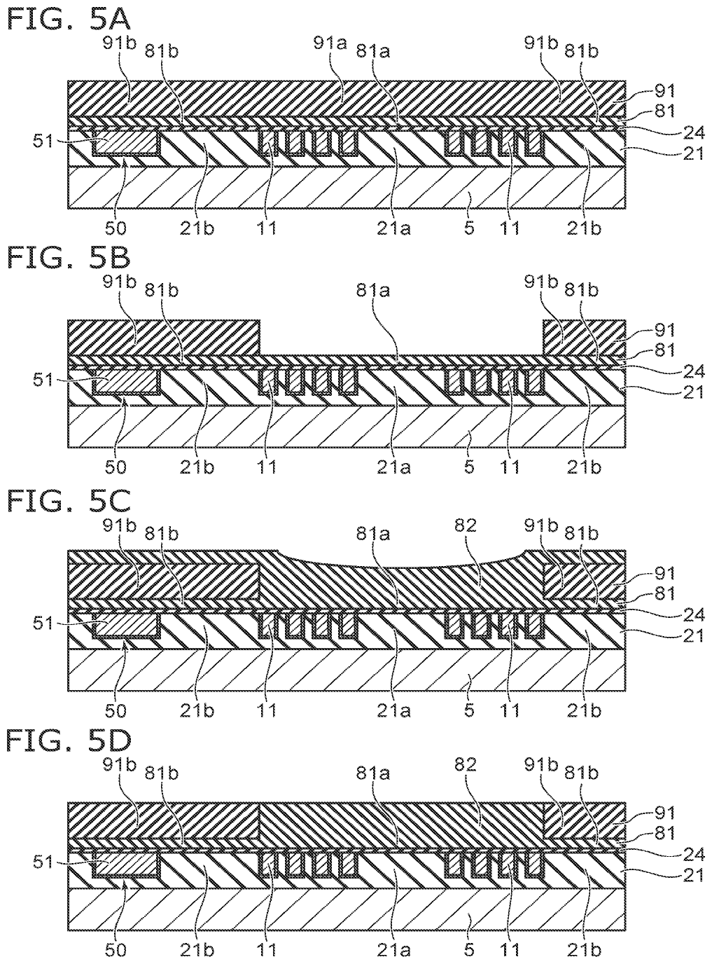

FIGS. 5A to 5D, FIGS. 6A to 6D, and FIGS. 7A to 7C are cross-sectional views illustrating a method for manufacturing the insulating device according to the first embodiment.

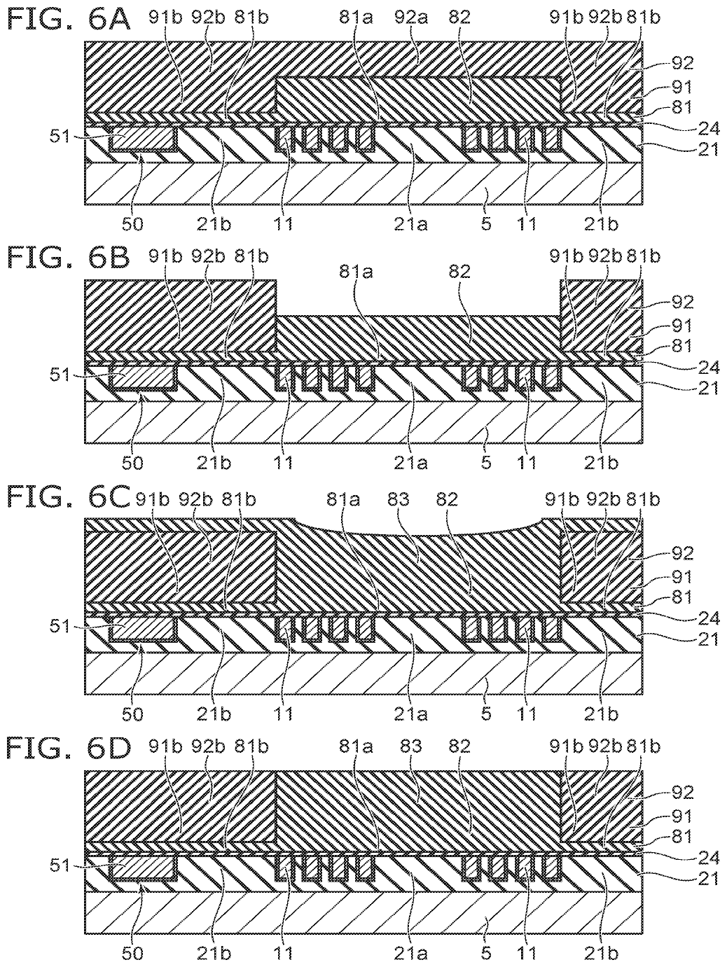

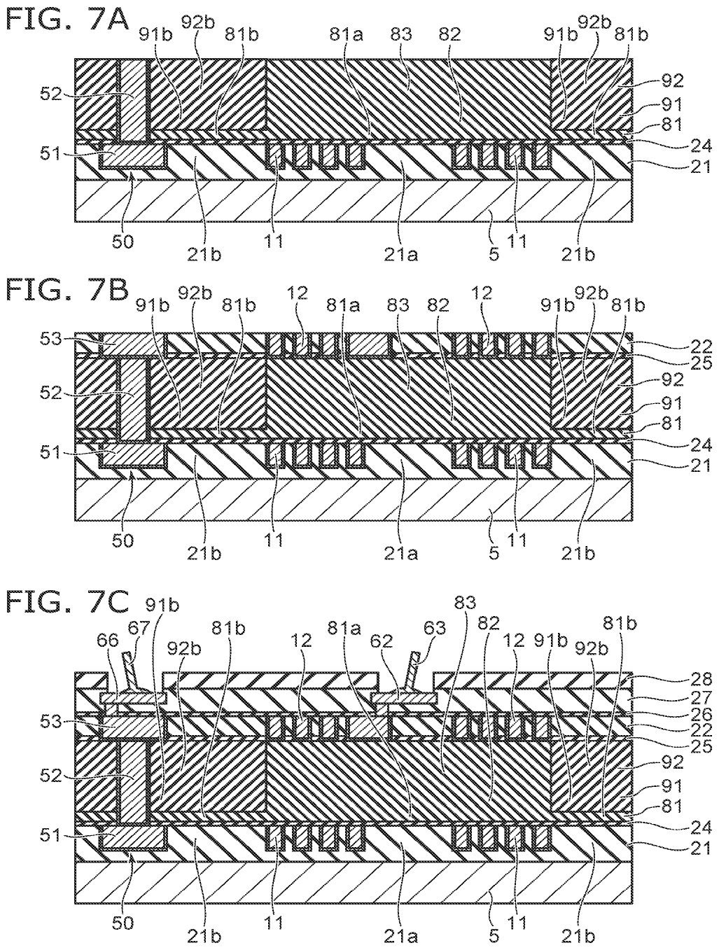

As illustrated in FIGS. 5A to 5D, FIGS. 6A to 6D, and FIGS. 7A to 7C, the method for manufacturing the insulating device according to the first embodiment includes a first process, a second process, a third process, a fourth process, a fifth process, a sixth process, a seventh process, and an eighth process. The second process is performed after the first process. The third process is performed after the second process. The fourth process is performed after the third process. The fifth process is performed after the fourth process. The sixth process is performed after the fifth process. The seventh process is performed after the sixth process. The eighth process is performed after the seventh process. FIG. 5A corresponds to the first and second processes. FIG. 5B corresponds to the third process. FIGS. 5C and 5D correspond to the fourth process. FIG. 6A corresponds to the fifth process. FIG. 6B corresponds to the sixth process. FIGS. 6C and 6D correspond to the seventh process. FIGS. 7A to 7C correspond to the eighth process.

In the first process as illustrated in FIG. 5A, a first silicon oxide film 81 is formed on the first insulating layer 21. In the example, the first silicon oxide film 81 is formed on the fourth insulating layer 24 formed on the first insulating layer 21. The first insulating layer 21 includes the first central insulating region 21a and the first outer perimeter insulating region 21b. The first outer perimeter insulating region 21b surrounds the first central insulating region 21a. The first coil 11 is located inside the first central insulating region 21a. In the example, the first conductive part 51 is located inside the first outer perimeter insulating region 21b. The first silicon oxide film 81 includes a first portion 81a and a second portion 81b. The first portion 81a overlaps the first central insulating region 21a. The second portion 81b overlaps the first outer perimeter insulating region 21b. The first portion 81a corresponds to a portion of the first center portion 23a1 described above. The second portion 81b corresponds to the first outer perimeter portion 23b1 described above. The first silicon oxide film 81 is formed by, for example, CVD (Chemical Vapor Deposition). The first coil 11 is formed by, for example, plating. The first conductive part 51 is formed by, for example, plating. The fourth insulating layer 24 is formed by, for example, CVD.

In the second process as illustrated in FIG. 5A, a first silicon oxynitride film 91 is formed on the first silicon oxide film 81. The first silicon oxynitride film 91 includes a third portion 91a and a fourth portion 91b. The third portion 91a overlaps the first portion 81a. The fourth portion 91b overlaps the second portion 81b. The fourth portion 91b corresponds to a portion of the second outer perimeter portion 23b2 described above. The first silicon oxynitride film 91 is formed by, for example, CVD.

In the third process as illustrated in FIG. 5B, the first portion 81a is exposed by removing the third portion 91a. The third portion 91a is removed by, for example, RIE (Reactive Ion Etching).

In the fourth process, first, as illustrated in FIG. 5C, a second silicon oxide film 82 is formed on the first portion 81a. In the example, the second silicon oxide film 82 is formed not only on the first portion 81a but also on the fourth portion 91b. The second silicon oxide film 82 is formed by, for example, CVD.

Then, in the fourth process as illustrated in FIG. 5D, the portion of the second silicon oxide film 82 that is positioned higher than the fourth portion 91b is removed. The portion of the second silicon oxide film 82 that remains without being removed corresponds to a portion of the first center portion 23a1 described above. The second silicon oxide film 82 is removed by, for example, CMP (Chemical Mechanical Polishing).

In the fifth process as illustrated in FIG. 6A, a second silicon oxynitride film 92 is formed on the second silicon oxide film 82 and the fourth portion 91b. The second silicon oxynitride film 92 includes a fifth portion 92a and a sixth portion 92b. The fifth portion 92a overlaps the second silicon oxide film 82. The sixth portion 92b overlaps the fourth portion 91b. The sixth portion 92b corresponds to a portion of the second outer perimeter portion 23b2 described above. The second silicon oxynitride film 92 is formed by, for example, CVD.

In the sixth process as illustrated in FIG. 6B, the second silicon oxide film 82 is exposed by removing the fifth portion 92a. The fifth portion 92a is removed by, for example, RIE.

In the seventh process, first, as illustrated in FIG. 6C, a third silicon oxide film 83 is formed on the second silicon oxide film 82. In the example, the third silicon oxide film 83 is formed not only on the second silicon oxide film 82, but also on the sixth portion 92b. The third silicon oxide film 83 is formed by, for example, CVD.

Then, in the seventh process as illustrated in FIG. 6D, the portion of the third silicon oxide film 83 that is positioned higher than the sixth portion 92b is removed. The portion of the third silicon oxide film 83 that remains without being removed corresponds to a portion of the first center portion 23a1 described above. The third silicon oxide film 83 is removed by, for example, CMP.

In the eighth process, first, as illustrated in FIG. 7A, the first conductive part 51 is exposed by removing portions of the second portion 81b, the fourth portion 91b, the sixth portion 92b, and the fourth insulating layer 24 that overlap the first conductive part 51. Then, the second conductive part 52 is formed on the first conductive part 51. The second portion 81b, the fourth portion 91b, the sixth portion 92b, and the fourth insulating layer 24 are removed by, for example, RIE. The second conductive part 52 is formed by, for example, plating.

Then, in the eighth process as illustrated in FIG. 7B, the second insulating layer 22 is formed on the third silicon oxide film 83 and the sixth portion 92b. In the example, the second insulating layer 22 is formed on the fifth insulating layer 25 formed on the third silicon oxide film 83 and the sixth portion 92b. The second insulating layer 22 includes the second central insulating region 22a and the second outer perimeter insulating region 22b. The second central insulating region 22a overlaps the third silicon oxide film 83. The second outer perimeter insulating region 22b overlaps the sixth portion 92b. The second outer perimeter insulating region 22b surrounds the second central insulating region 22a. The second coil 12 is located inside the second central insulating region 22a. In the example, the third conductive part 53 is located inside the second outer perimeter insulating region 22b at a position at which the third conductive part 53 overlaps the first conductive part 51. The second insulating layer 22 is formed by, for example, CVD. The second coil 12 is formed by, for example, plating. The third conductive part 53 is formed by, for example, plating. The fifth insulating layer 25 is formed by, for example, CVD.

Continuing, in the eighth process as illustrated in FIG. 7C, the sixth insulating layer 26 is formed on the second insulating layer 22. Then, the seventh insulating layer 27 is formed on the sixth insulating layer 26. Then, the eighth insulating layer 28 is formed on the seventh insulating layer 27. Then, the pad 62 and the pad 66 are formed by removing portions of the seventh and eighth insulating layers 27 and 28. The sixth insulating layer 26 is formed by, for example, CVD. The seventh insulating layer 27 is formed by, for example, CVD. The eighth insulating layer 28 is formed by, for example, CVD. The seventh insulating layer 27 and the eighth insulating layer 28 are removed by, for example, RIE. The pad 62 and the pad 66 are formed by, for example, sputtering.

According to the method for manufacturing the insulating device according to the embodiment, an insulating device can be easily manufactured in which the insulation life can be improved by increasing the ratio of silicon oxide, which has a greater insulation life than silicon oxynitride, at the portion positioned between the first coil 11 and the second coil 12; and the warp can be suppressed by increasing the ratio of silicon oxynitride, which has less stress than silicon oxide, at portions not positioned between the first coil 11 and the second coil 12. Accordingly, an insulating device can be easily manufactured in which both the improvement of the insulation life and the suppression of the warp can be realized, and the reliability can be increased.

The formation of the silicon oxynitride film, the removal of a portion of the silicon oxynitride film, and the formation of the silicon oxide film may be performed in the second to fourth processes of the example above as a first set; and the formation of the silicon oxynitride film, the removal of a portion of the silicon oxynitride film, and the formation of the silicon oxide film may be performed in the fifth to seventh processes as a second set. That is, in the example above, the formation of the silicon oxynitride film, the removal of a portion of the silicon oxynitride film, and the formation of the silicon oxide film are divided into multiple sets. By dividing the formation of the silicon oxynitride film, the removal of a portion of the silicon oxynitride film, and the formation of the silicon oxide film into multiple sets, the thicknesses of the silicon oxide film and/or silicon oxynitride film formed per set can be reduced. The stress when forming a silicon oxide film and/or silicon oxynitride film can be suppressed thereby.

Although two sets of the formation of the silicon oxynitride film, the removal of a portion of the silicon oxynitride film, and the formation of the silicon oxide film are performed in the method for manufacturing the insulating device according to the embodiment in the example above, three or more sets may be performed.

According to embodiments described above, an insulating device can be realized in which both the improvement of the insulation life and the suppression of the warp can be realized.

Embodiments may include the following configurations.

### Configuration 1

An insulating device, comprising:
an insulating part;
a first coil located inside the insulating part; and
a second coil located inside the insulating part,
the second coil facing the first coil in a first direction,
the insulating part including
   a first insulating layer, the first coil being located inside the first insulating layer,
   a second insulating layer, the second coil being located inside the second insulating layer, and
   a third insulating layer positioned between the first insulating layer and the second insulating layer in the first direction,
the first insulating layer including
   a first central insulating region, the first coil being located inside the first central insulating region, and
   a first outer perimeter insulating region surrounding the first central insulating region along a first plane perpendicular to the first direction,
the second insulating layer including
   a second central insulating region, the second coil being located inside the second central insulating region, and
   a second outer perimeter insulating region surrounding the second central insulating region along the first plane,
the third insulating layer including
   a third central insulating region positioned between the first central insulating region and the second central insulating region in the first direction, and
   a third outer perimeter insulating region positioned between the first outer perimeter insulating region and the second outer perimeter insulating region in the first direction,
the third central insulating region including a first center portion including silicon oxide,
the third outer perimeter insulating region including
   a first outer perimeter portion including silicon oxide, and
   a second outer perimeter portion positioned between the first outer perimeter portion and the second outer perimeter insulating region in the first direction, the second outer perimeter portion including silicon oxynitride,
a thickness in the first direction of the first center portion being greater than a thickness in the first direction of the first outer perimeter portion,
a thickness in the first direction of the second outer perimeter portion being greater than the thickness in the first direction of the first outer perimeter portion.

### Configuration 2

The device according to configuration 1, wherein
the thickness in the first direction of the first center portion is greater than the thickness in the first direction of the second outer perimeter portion.

### Configuration 3

The device according to configuration 1 or 2, wherein
the thickness in the first direction of the first center portion is equal to a total of the thickness in the first direction of the first outer perimeter portion and the thickness in the first direction of the second outer perimeter portion.

### Configuration 4

The device according to any one of configurations 1 to 3, wherein
the first center portion is a multilayer film including silicon oxide, and
the second outer perimeter portion is a multilayer film including silicon oxynitride.

### Configuration 5

A method for manufacturing an insulating device, the method comprising:
a first process of forming a first silicon oxide film on a first insulating layer, the first insulating layer including a first central insulating region and a first outer perimeter insulating region, a first coil being located inside the first central insulating region, the first outer perimeter insulating region surrounding the first central insulating region, the first silicon oxide film including a first portion and a second portion, the first portion overlapping the first central insulating region, the second portion overlapping the first outer perimeter insulating region;
a second process of forming a first silicon oxynitride film on the first silicon oxide film, the first silicon oxynitride film including a third portion and a fourth portion, the third portion overlapping the first portion, the fourth portion overlapping the second portion;
a third process of exposing the first portion by removing the third portion;
a fourth process of forming a second silicon oxide film on the first portion;
a fifth process of forming a second silicon oxynitride film on the second silicon oxide film and the fourth portion, the second silicon oxynitride film including a fifth portion and a sixth portion, the fifth portion overlapping the second silicon oxide film, the sixth portion overlapping the fourth portion;
a sixth process of exposing the second silicon oxide film by removing the fifth portion;
a seventh process of forming a third silicon oxide film on the second silicon oxide film; and
an eighth process of forming a second insulating layer on the third silicon oxide film and the sixth portion, the second insulating layer including a second central insulating region and a second outer perimeter insulating region, the second central insulating region overlapping the third silicon oxide film, a second coil being located inside the second central insulating region, the second outer perimeter insulating region overlapping the sixth portion and surrounding the second central insulating region.

While certain embodiments have been described, these embodiments have been presented by way of example only, and are not intended to limit the scope of the inventions. Indeed, the novel embodiments described herein may be embodied in a variety of other forms; furthermore, various omissions, substitutions, and changes in the form of the embodiments described herein may be made without departing from the spirit of the inventions. The accompanying claims and their equivalents are intended to cover such forms or modifications as would fall within the scope and spirit of the inventions. Embodiments described above can be implemented in combination with each other.

What is claimed is:

1. An insulating device, comprising:
an insulating part;
a first coil located inside the insulating part; and
a second coil located inside the insulating part,
the second coil facing the first coil in a first direction,
the insulating part including
a first insulating layer, the first coil being located inside the first insulating layer,
a second insulating layer, the second coil being located inside the second insulating layer, and
a third insulating layer positioned between the first insulating layer and the second insulating layer in the first direction,
the first insulating layer including
a first central insulating region, the first coil being located inside the first central insulating region, and
a first outer perimeter insulating region surrounding the first central insulating region along a first plane perpendicular to the first direction,
the second insulating layer including
a second central insulating region, the second coil being located inside the second central insulating region, and
a second outer perimeter insulating region surrounding the second central insulating region along the first plane,
the third insulating layer including
a third central insulating region positioned between the first central insulating region and the second central insulating region in the first direction, and
a third outer perimeter insulating region positioned between the first outer perimeter insulating region and the second outer perimeter insulating region in the first direction,
the third central insulating region including a first center portion including silicon oxide,
the third outer perimeter insulating region including
a first outer perimeter portion including silicon oxide, and
a second outer perimeter portion positioned between the first outer perimeter portion and the second outer perimeter insulating region in the first direction, the second outer perimeter portion including silicon oxynitride,
a thickness in the first direction of the first center portion being greater than a thickness in the first direction of the first outer perimeter portion,
a thickness in the first direction of the second outer perimeter portion being greater than the thickness in the first direction of the first outer perimeter portion.

2. The device according to claim 1, wherein
the thickness in the first direction of the first center portion is greater than the thickness in the first direction of the second outer perimeter portion.

3. The device according to claim 1, wherein
the thickness in the first direction of the first center portion is equal to a total of the thickness in the first direction of the first outer perimeter portion and the thickness in the first direction of the second outer perimeter portion.

4. The device according to claim 1, wherein
the first center portion is a multilayer film including silicon oxide, and
the second outer perimeter portion is a multilayer film including silicon oxynitride.

5. A method for manufacturing an insulating device, the method comprising:
a first process of forming a first silicon oxide film on a first insulating layer, the first insulating layer including a first central insulating region and a first outer perimeter insulating region, a first coil being located inside the first central insulating region, the first outer perimeter insulating region surrounding the first central insulating region, the first silicon oxide film including a first portion and a second portion, the first portion overlapping the first central insulating region, the second portion overlapping the first outer perimeter insulating region;
a second process of forming a first silicon oxynitride film on the first silicon oxide film, the first silicon oxynitride film including a third portion and a fourth portion, the third portion overlapping the first portion, the fourth portion overlapping the second portion;
a third process of exposing the first portion by removing the third portion;
a fourth process of forming a second silicon oxide film on the first portion;
a fifth process of forming a second silicon oxynitride film on the second silicon oxide film and the fourth portion, the second silicon oxynitride film including a fifth portion and a sixth portion, the fifth portion overlapping the second silicon oxide film, the sixth portion overlapping the fourth portion;
a sixth process of exposing the second silicon oxide film by removing the fifth portion;
a seventh process of forming a third silicon oxide film on the second silicon oxide film; and
an eighth process of forming a second insulating layer on the third silicon oxide film and the sixth portion, the second insulating layer including a second central insulating region and a second outer perimeter insulating region, the second central insulating region overlapping the third silicon oxide film, a second coil being located inside the second central insulating region, the second outer perimeter insulating region overlapping the sixth portion and surrounding the second central insulating region.
